(19) United States
(12) Patent Application Publication
(10) Pub. No.: US 2026/0018853 A1
(43) Pub. Date: Jan. 15, 2026

(54) SEMICONDUCTOR LASER DEVICE

(71) Applicant: Panasonic Holdings Corporation, Osaka (JP)

(72) Inventors: HIROSHI OHNO, Osaka (JP); HIROAKI SUZUKI, Osaka (JP); HITOSHI NAGANO, Osaka (JP)

(21) Appl. No.: 19/330,883

(22) Filed: Sep. 17, 2025

Related U.S. Application Data
(63) Continuation of application No. PCT/JP2024/001335, filed on Jan. 18, 2024.

(30) Foreign Application Priority Data
Mar. 29, 2023 (JP) 2023-054115

(51) Int. Cl. H01S 5/0222; H01S 5/323

(52) U.S. Cl. CPC H01S 5/0222; H01S 5/32341

(57) ABSTRACT

A semiconductor laser device having an emission end surface of laser light includes: a semiconductor laser element; an oscillator housing having airtightness; and a gas circulation system including a circulation pump and a siloxane remover and connected to a supply port and an exhaust port of the oscillator housing, in which in the oscillator housing, the semiconductor laser element is disposed with the emission end surface of the laser light being exposed from the oscillator housing, and an optical member and an electric wiring member are also disposed, and when the gas circulation system is operated, the oscillator housing has an inside having an equilibrium siloxane concentration of 0.1 μg/m³ or less.

### TECHNICAL FIELD

The present disclosure relates to a semiconductor laser device.

### BACKGROUND ART

In recent years, high-power laser processing systems useful for applications such as welding, cutting, drilling, and material processing have been developed. Among them, a laser processing system of a direct diode laser (DDL) method using a semiconductor laser element as a light source is highly efficient because laser light from a semiconductor laser device is not converted but directly used for processing. In particular, laser light having a short wavelength such as blue laser light has a higher absorptivity in copper than laser light having an infrared wavelength, and is suitable for laser processing of electric vehicle (EV)-related secondary batteries and electronic components in which a copper material is used much. Hereinafter, a laser processing system of the DDL method using a short wavelength laser light including a blue laser light is referred to as a “blue DDL processing system”.

The high-power blue DDL processing system described above requires light outputs of several hundred kilowatts to several kilowatts. The output of the semiconductor laser element is about several watts per emitter that is a light emitting unit. Therefore, in the blue DDL processing system, for example, a semiconductor laser element is employed that has a multi-emitter structure in which a plurality of emitters are arranged in an array. Furthermore, there is also a semiconductor laser device in which a plurality of semiconductor laser elements having a multi-emitter structure is mounted, and laser beams from the individual semiconductor laser elements are synthesized to obtain a high-power laser beam.

Meanwhile, in a gallium nitride (GAN)-based semiconductor laser element capable of emitting a blue laser light, it is known that compounds having silicon(S) and oxygen (O) as a skeleton, more specifically, fouling substances such as siloxanes that are compounds having Si—O—Si bonds, react and decompose due to the light emitted by the semiconductor laser element, and deposit on the laser light emission end surface.

Since the end surface deposits derived from siloxane increase with the operation time of the semiconductor laser element, the end surface deposits become a factor that deteriorate the output characteristics over time, and affect the reliability of the laser processing system. In order to prevent characteristic deterioration due to the end surface fouling, the GaN-based semiconductor laser element is generally used in a form of a package (so-called CAN package) airtightly sealed with the internal gas atmosphere kept clean. In addition, PTLs 1 and 2 disclose that a clean gas is allowed to flow in a housing that houses a semiconductor laser element as a technique for preventing end surface fouling of the semiconductor laser element.

### CITATION LIST

### Patent Literatures

PTL 1: Unexamined Japanese Patent Publication No. 2002-144073
PTL 2: Unexamined Japanese Patent Publication No. 2004-126001

### SUMMARY OF THE INVENTION

A semiconductor laser device according to the present disclosure includes:
a semiconductor laser element having an emission end surface of laser light;
an oscillator housing having airtightness; and
a gas circulation system including a circulation pump and a siloxane remover and connected to a supply port and an exhaust port of the oscillator housing,
in which in the oscillator housing, the semiconductor laser element is disposed with the emission end surface of the laser light being exposed from the oscillator housing, and an optical member and an electric wiring member are also disposed, and
when the gas circulation system is operated, the oscillator housing has an inside having an equilibrium siloxane concentration of 0.1 μg/m³ or less.

### BRIEF DESCRIPTION OF THE DRAWINGS

FIG. 1 is a graph illustrating an example of a temporal change in light output of a GaN-based semiconductor element.

FIG. 2A is a view illustrating a result of observing an emission end surface of a semiconductor laser element after deterioration with an AFM.

FIG. 2B is a view illustrating a result of observing the emission end surface of the semiconductor laser element after deterioration with an AFM.

FIG. 3 is a view illustrating a result of analysis with a TEM of a cross-sectional structure of a portion having a large projection in the observation result with the AFM.

FIG. 4 is a table summarizing low molecular weight cyclic siloxanes each with a proper name and a chemical formula, a molecular weight, a melting point, a boiling point, and a vapor pressure.

FIG. 5A is a schematic diagram of a molecular structure of a cyclic siloxane of D3.

FIG. 5B is a schematic diagram of a molecular structure of a cyclic siloxane of D4.

FIG. 5C is a schematic diagram of a molecular structure of a cyclic siloxane of D5.

FIG. 6 is a diagram illustrating a process in which fouling substances derived from siloxane (SiOₓ) are deposited on an emission end surface of a semiconductor laser element.

FIG. 7 is a diagram showing bond dissociation energy of bonds based on Si or C.

FIG. 8 is a diagram illustrating a configuration of a semiconductor laser device according to a first exemplary embodiment.

FIG. 9 is a diagram schematically illustrating a principle of an SBC method.

FIG. 10 is a diagram schematically illustrating a principle of a WBC method.

FIG. 11 is a diagram illustrating changes in reflectances on an end surface of the semiconductor laser element.

FIG. 12 is a diagram illustrating SiOₓ deposition amount dependency of reflectances on an end surface in an AR coating film.

FIG. 13 is a diagram illustrating a relationship between siloxane concentrations and SiOₓ deposition rates.

FIG. 14 is a diagram illustrating a relationship between replacement efficiencies by a circulation pump and reached siloxane concentrations.

FIG. 15 is a diagram illustrating a relationship between filter performances of siloxane removal filters and equilibrium siloxane concentrations inside an oscillator housing.

FIG. 16 is a diagram illustrating a relationship between gas leak rates and equilibrium siloxane concentrations inside an oscillator housing.

FIG. 17 is a diagram illustrating a relationship between siloxane generation rates and the siloxane concentrations inside the oscillator housing.

FIG. 18 is a diagram for describing a positional relationship between a supply port and an exhaust port in the oscillator housing.

FIG. 19 is a diagram illustrating a configuration of a semiconductor laser device according to a second exemplary embodiment.

### DESCRIPTION OF EMBODIMENTS

In a high-power laser processing system, optical members such as a microlens array and a condenser lens need to be precisely disposed in the same housing as the semiconductor laser element, and the number of components for fixing the members tends to increase. This makes various fouling factors. Therefore, as disclosed in PTLs 1 and 2, it is difficult to completely prevent end surface contamination due to fouling substances derived from siloxane even if a clean gas is allowed to flow in from the outside. In addition, as in PTL 2, a method of filling and circulating an inert gas in a housing to keep the inside clean requires a cylinder and a filling system for periodically filling the inert gas, and maintenance cost increases.

An object of the present disclosure is to provide a highly reliable semiconductor laser device capable of preventing end surface fouling due to fouling substances derived from siloxane in a semiconductor laser element.

### [Circumstances]

First, circumstances are to be described in which the inventors of the present invention have conceived the present disclosure. The inventors of the present invention have examined in detail generation of end surface deposits in a semiconductor laser element that is not made airtight, and have studied mechanisms to study a method for preventing the end surface deposits.

Here, the semiconductor laser element that is not made airtight means not a semiconductor laser element airtightly sealed in a package in a state in which an internal gas atmosphere is kept clean like a CAN package, but a semiconductor laser element disposed in an oscillator housing in a state in which an emission end surface of laser light is exposed.

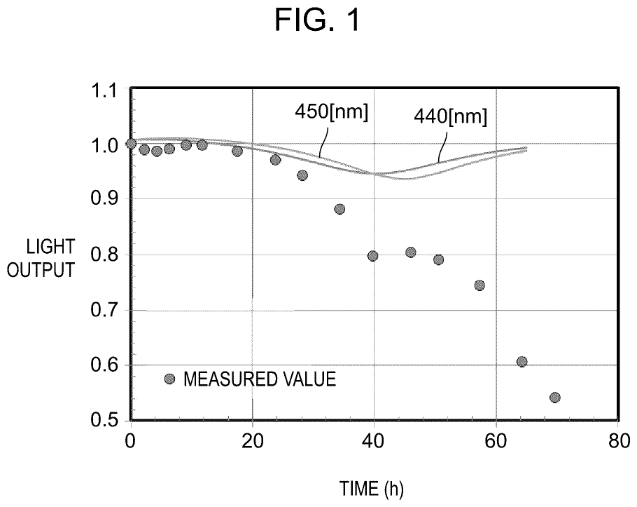

FIG. 1 is a graph illustrating a temporal change in light output when a GaN-based semiconductor laser element is caused to continuously emit light at a constant current in an environment in which a siloxane concentration is set high. FIG. 1 demonstrates that the light output decreases with time, and the light output decreases to about 55% in 70 hours.

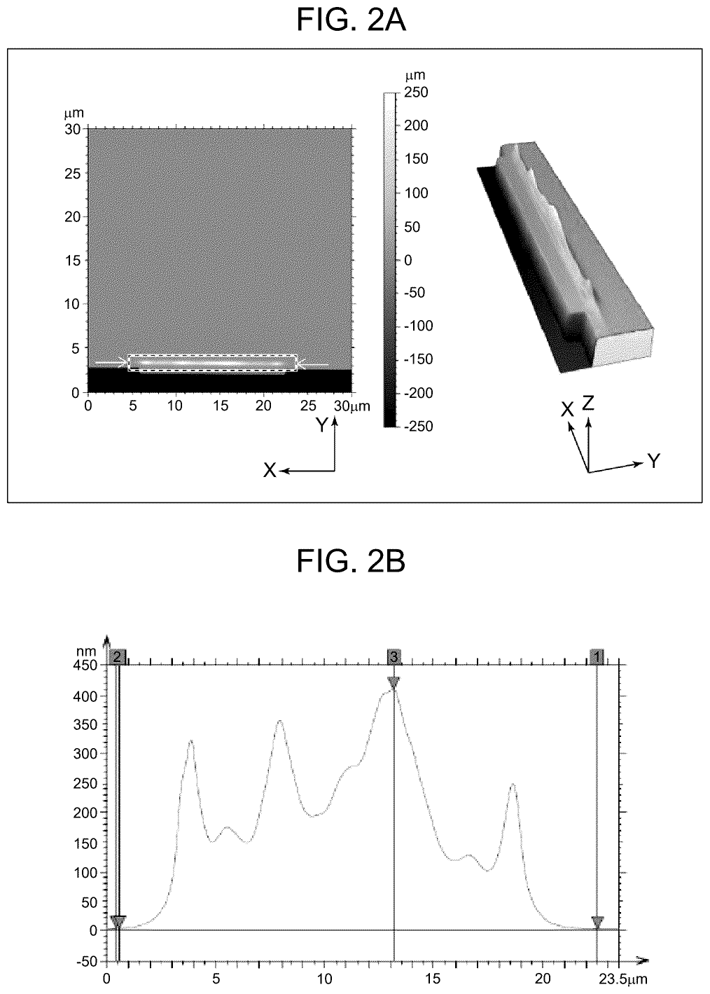

FIG. 2A and FIG. 2B are views illustrating a result of observing the emission end surface of the semiconductor laser element after deterioration with an atomic force microscopy (AFM), and illustrate the irregularities shape of the surface. FIG. 2B illustrates the irregularities shape of the region surrounded by the broken line in FIG. 2A with the projection height on the vertical axis.

As can be seen from FIG. 2A and FIG. 2B, a projection shape having a plurality of peaks is formed on the emission end surface of the semiconductor laser element after deterioration. In addition, since the waveguide mode of the semiconductor laser element used for the observation is a multimode and a plurality of waveguide modes are present in the width direction of the waveguide, it is considered that the deposition amount of the end surface deposits changes in accordance with the intensity distribution of the light, and a plurality of peaks appear. In other words, the deposition amount of the end surface deposits tends to increase as the light intensity increases. As a result of observation of the irregularities on the surface of the emission end surface by an AFM, the average thickness of the end surface deposits is about 140 nm.

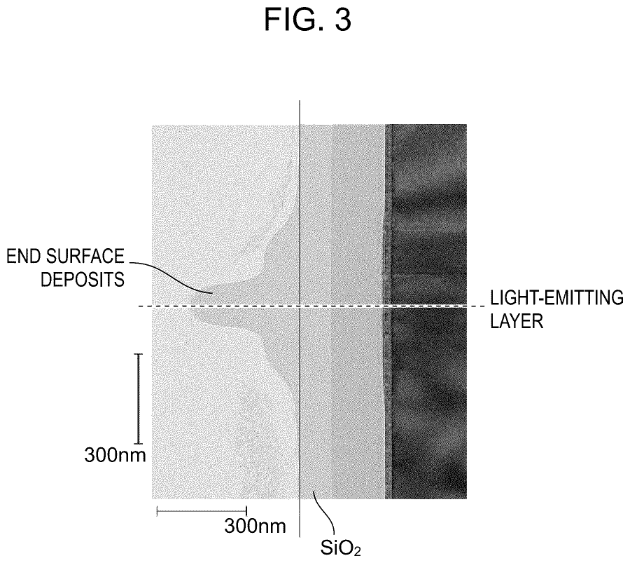

FIG. 3 is a view illustrating a result of analysis with a transmission electron microscopy (TEM) of a cross-sectional structure of the portion having the large projection in the observation result with the AFM (see FIG. 2A).

FIG. 3 demonstrates that the end surface deposits are formed along the light distribution in the semiconductor laser element with the light-emitting layer at the center. In addition, a result of composition analysis by an energy dispersive X-ray spectroscopy (EDX) has demonstrated that the end surface deposits include Si and O, and are almost made of SiO₂ from the composition ratio. In addition, carbon (C) is not detected and is less than or equal to the lower detection limit of EDX analysis. The deposition amount of the end surface deposits is about 450 [nm] at the thickest part, and this is consistent with the irregularities observation result of the AFM. As described above, the end surface deposits derived from siloxane in the semiconductor laser are determined to have a composition close to SiO₂, but in the present disclosure, the composition is represented by SiOₓ as SiO oxide in a broad sense.

Here, the definitions and types of siloxanes in the present disclosure are to be described. Siloxanes are roughly classified into linear siloxanes each having a linear structure and cyclic siloxanes each having a cyclic structure.

An organopolysiloxane in which linear siloxanes are long and continuous to form a polymer is called silicone. Silicone has a wide variety of forms by having branch or cyclic structures, and there are oily, rubber-like, resinous forms, and the like. A linear siloxane of a polymer is generally stable and hardly volatilizes in gas, but when separation progresses due to time degradation, thermal degradation, photodegradation, or the like, siloxanes of a low molecular weight may be released.

As described above, it is known that siloxanes contained in the air are generated by decomposition or volatilization from siloxane compounds, so that most of the siloxanes present in the air are low molecular weight siloxanes, and in particular, the amount of cyclic siloxanes is large. Low molecular weight linear siloxanes are structurally unstable and may convert form to cyclic siloxanes, and linear siloxanes are rarely present alone in the gas.

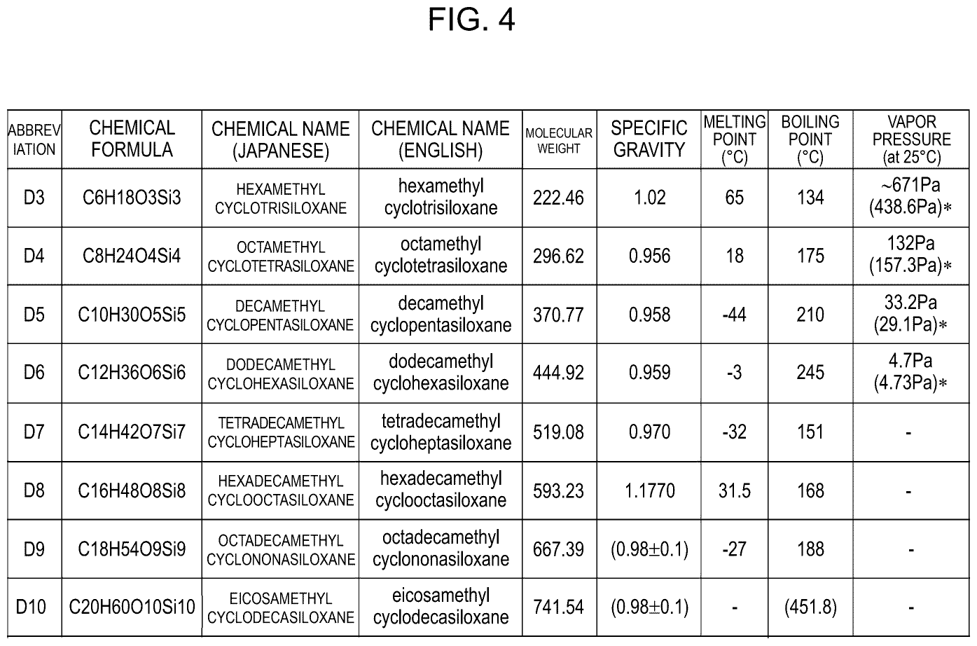

FIG. 4 is a table summarizing a proper name and a chemical formula, a molecular weight, a melting point, a boiling point, and a vapor pressure of each of the low molecular weight cyclic siloxanes.

As illustrated in FIG. 4, the cyclic siloxanes are each commonly referred to as D3, D4, D5, and the like from the number of Si atoms in the molecule. Cyclic siloxanes have a relatively high boiling point, but has a high vapor pressure to be likely to volatilize into the atmosphere. In particular, the cyclic siloxanes of D3 to D6 are molecules having high vapor pressure and high volatility.

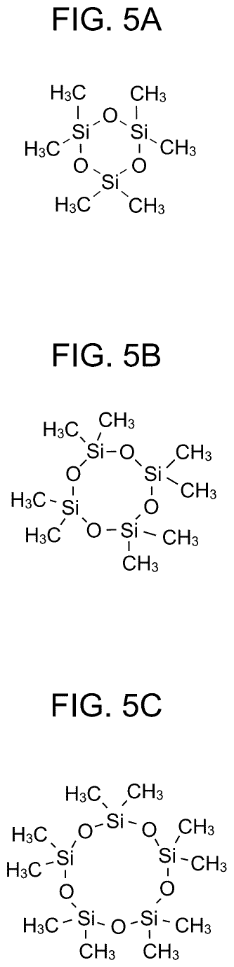

FIG. 5A to FIG. 5C are schematic diagrams of molecular structures of the cyclic siloxanes of D3 to D5.

As illustrated in FIG. 5A to FIG. 5C, the number of cyclic —Si—O—Si-junctions increases with the number of Si atoms, and the number of CH₃ also increases in proportion to the number of Si atoms, and the types of chemical bonds in the molecule are the same.

The siloxane concentration in the atmosphere can be quantitatively analyzed by analysis using a gas chromatograph-mass spectrometry (GC-MS). In the present disclosure, the integrated amount obtained by quantitatively analyzing the cyclic siloxanes of D3 to D9 in the atmosphere is defined as the siloxane concentration in the atmosphere. In other words, almost no siloxane larger than D10 is present in the air, and the amount of linear siloxanes present in the gas is smaller than amount of the cyclic siloxanes, and therefore, the linear siloxanes are excluded from the analysis target.

However, when a large amount of organic molecules having a siloxane bond or a silanol group are contained in molecules other than D3 to D9, it is appropriate to include those molecules in the siloxane concentration calculation. In the GC-MS analysis, molecules other than the cyclic siloxanes can also be detected at the same time, and therefore other siloxane compounds can also be quantitatively analyzed.

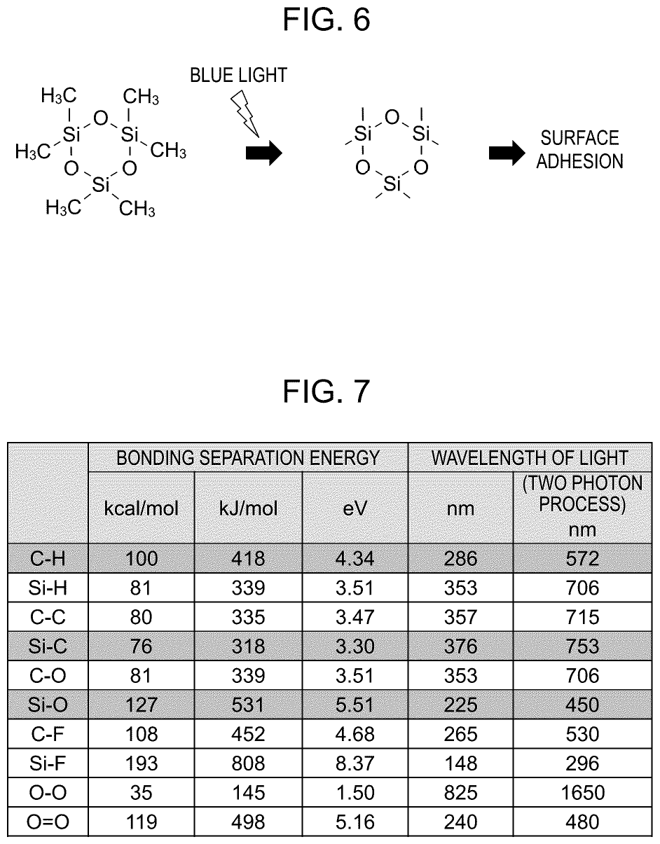

FIG. 6 is a diagram illustrating a process in which a fouling substance (SiOₓ) derived from siloxane is deposited on the emission end surface of the semiconductor laser element by a photochemical reaction between a cyclic siloxane of D3 and blue laser light.

As illustrated in FIG. 6, Si—C bonds and Si—O bonds in the cyclic siloxane are broken (dissociated) by a photochemical reaction between the cyclic siloxane and blue laser light to generate a radical of —Si—O—. The radical is then deposited as inorganic SiOₓ on the emission end surface of the semiconductor laser element. In other words, to deposit the cyclic siloxanes as inorganic SiOₓ on the emission end surface, energy is required that is capable of dissociating the Si—C bonds and the Si—O bonds in the cyclic siloxanes.

FIG. 7 is calculated values of bond dissociation energy of various bonds based on Si or C.

From FIG. 7, it is expected that a large energy is required to dissociate Si—O bonds and Si—C bonds, and when the energy is converted into a wavelength, a wavelength of 400 nm or less is required. This numerical values are not consistent with the actual situation in which the end surface deposits of SiOₓ occur in a GaN-based semiconductor laser element that emits blue laser light having a wavelength of 550 nm, but the end surface deposits may occur in a two-photon absorption process that occurs under a situation of very strong light density.

As described above, on the emission end surface of the semiconductor laser element, inorganic SiOₓ products are deposited by a photochemical reaction of silicon compounds having siloxane bonds (—Si—O—Si—) represented by a low molecular weight siloxane or silicon compounds having silanol groups (Si—O—H). In addition, a phenomenon is also known in which carbon compounds mainly having carbons (C) are deposited on the emission end surface by reaction of organic compounds having CH₃ groups.

With regard to the deposition of the carbon compounds, when oxygen (O) is present in the atmosphere, a reaction also occurs in which the carbon compounds are desorbed as CO₂ by a photochemical reaction. Therefore, the deposition causes almost no problem in the air, and is likely to cause a problem in light emission in a nitrogen atmosphere or an inert gas atmosphere. In contrast, regarding the deposition of SiOₓ, there is a report that the deposition reaction of siloxane can be prevented when the amount of oxygen (O) in the atmosphere is small, and there is also a proposal to control the oxygen concentration in ppm order. However, it is very difficult to precisely control the oxygen concentration inside the housing that is not completely airtight, and the use of an inert gas or the like is also unrealistic because the system is large-scale and causes increase in cost.

The inventors of the present invention have conducted intensive studies in order to solve the problem of end surface contamination derived from siloxane, the problem having a large influence on the reliability of the semiconductor laser element and requires a thorough reduction measure. Then, the present inventors have completed a semiconductor laser device according to the present disclosure capable of preventing end surface contamination derived from siloxane at relatively low cost.

Hereinafter, exemplary embodiments of the present disclosure are detailed with reference to the drawings. Note that the exemplary embodiments described below illustrate specific examples of the present disclosure, and numerical values, shapes, materials, components, disposed positions and connection modes of the components, steps, order of the steps, and the like are merely examples, and are not intended to limit the present disclosure. The present disclosure is limited only by the scope of the claims.

### First Exemplary Embodiment

### <Configuration of Semiconductor Laser Device>

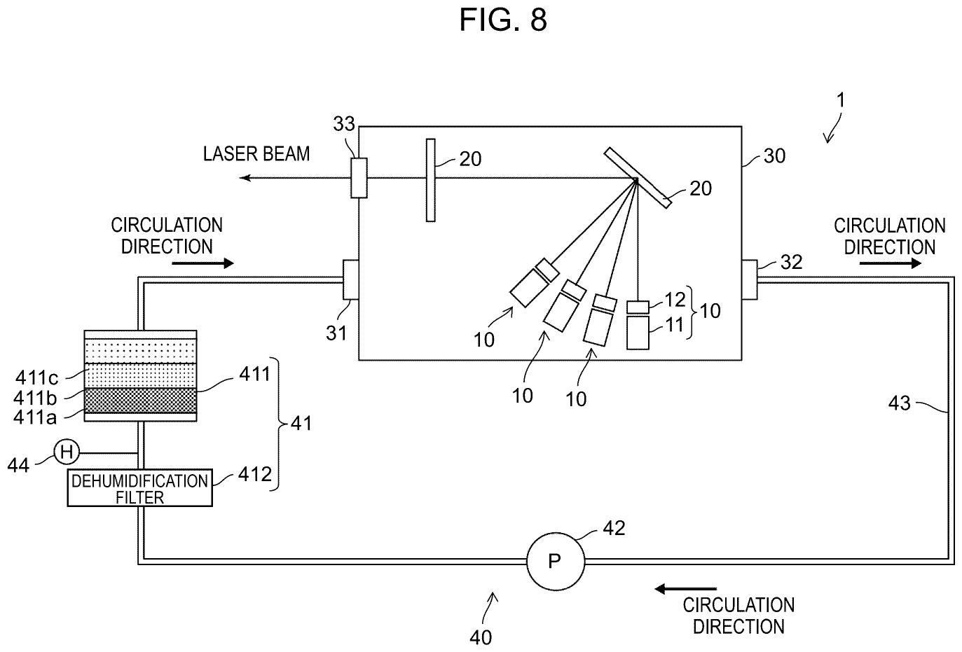

FIG. 8 is a diagram illustrating a configuration of semiconductor laser device 1 according to an exemplary embodiment of the present disclosure.

As illustrated in FIG. 8, semiconductor laser device 1 includes semiconductor laser modules 10, optical members 20, oscillator housing 30, and gas circulation system 40. Semiconductor laser device 1 is, for example, a blue DDL processing system to be used for laser processing of a secondary battery, an electronic component related to an electric vehicle (EV), and the like.

Semiconductor laser modules 10 and optical members 20 are disposed inside oscillator housing 30. In addition, gas circulation system 40 is connected to supply port 31 and exhaust port 32 provided in oscillator housing 30. The entire gas circulation system including oscillator housing 30 and gas circulation system 40 is filled with a predetermined gas so as to be able to circulate. The gas to be circulated may be, for example, the air or dry air obtained by removing moisture from the air.

Each semiconductor laser module 10 is a module in which semiconductor laser element 11 having a multi-emitter structure is mounted on a heat dissipation package, and includes intra-module optical component 12. The laser beams emitted from semiconductor laser modules 10 are condensed through optical members 20 and emitted to the outside from optical window 33 of oscillator housing 30.

Each semiconductor laser element 11 is, for example, a GaN-based nitride semiconductor laser element, and emits laser light in a wavelength band of 500 nm or less (blue to ultraviolet band). The photochemical reaction of siloxane is known to be observed at a wavelength of 550 nm or less, and is more remarkable as the wavelength is shorter. When semiconductor laser element 11 includes a GaN-based semiconductor laser element, measures are necessary for preventing end surface fouling due to fouling substances derived from siloxane.

Each intra-module optical component 12 is an optical component disposed in the vicinity of the emission end surface of semiconductor laser element 11, and is connected to semiconductor laser element 11 via a fixing member or an adhesive (not illustrated). Intra-module optical component 12 has, for example, a function of converting laser beams emitted from semiconductor laser element 11 into collimated beams, a function of rotating cross-sectional shapes of the laser beams on a plane perpendicular to a laser propagation direction, a function of separating laser beams, and the like. Intra-module optical component 12 is, for example, a beam twister unit including a plurality of lenses.

Although not illustrated, copper wires called bus bars are connected to each semiconductor laser element 11 as electric wires for power supply. The package of each semiconductor laser module 10 includes a water-cooling mechanism for heat dissipation.

Optical members 20 are components constituting an optical system of a laser oscillator, and for example, a plurality of laser beams emitted from semiconductor laser modules 10 are incident on optical members 20 in the process of being emitted to the outside.

Gas circulation system 40 includes siloxane remover 41, circulation pump 42, gas pipe 43, and humidity detector 44. Siloxane remover 41 and circulation pump 42 are connected to gas pipe 43. Gas pipe 43 is connected to supply port 31 and exhaust port 32 of oscillator housing 30. Siloxane remover 41 is disposed between supply port 31 of oscillator housing 30 and the exhaust port of circulation pump 42.

Siloxane remover 41 removes siloxane in the gas circulating in gas circulation system 40. In the present exemplary embodiment, siloxane remover 41 includes two types of filters: siloxane removal filter 411 and dehumidification filter 412.

Siloxane removal filter 411 is a filter member filled with an adsorption material that mainly removes siloxane. Siloxane removal filter 411 is preferably filled with a plurality of types of adsorption materials. In FIG. 8, siloxane removal filter 411 is filled with three types of adsorption materials 411a to 411c in layers.

Siloxanes have a plurality of molecular structures, such as D3 to D9 (see FIG. 4), and the size of the molecules varies. An adsorbent for removing siloxane has an adsorption site size that determines the molecular size to be easily adsorbed, and in order to efficiently adsorb a plurality of types of siloxanes, it is desirable to use several types of adsorbents having different characteristics.

The adsorbents to be used can be various adsorbents such as activated carbon, zeolite, molecular sieve, activated alumina, silica gel, and synthetic resin adsorbent. It is also effective to use a combination of activated carbon of the same type but with different pore sizes. Combining different pore sizes, different materials, and different adsorption mechanisms allows various types of siloxane molecules to be adsorbed without fail, and it is therefore preferable to combine at least two types of adsorbents.

Note that, in FIG. 8, siloxane removal filter 411 is filled with three types of adsorbents 411a to 411c in three separate layers, but a plurality of types of adsorbents may be mixed and filled.

Dehumidification filter 412 is a filter member filled with a moisture absorbent (for example, calcium chloride) that mainly removes moisture. Dehumidification filter 412 can use a moisture absorbent of a type in which discoloration occurs together with moisture absorption such as silica gel, to detect the filter replacement time.

Siloxane removal filter 411 is disposed downstream of dehumidification filter 412 in the gas circulation direction.

For adsorbents of siloxane removal filter 411, various adsorbents can be used, but there is no adsorbent that adsorbs only siloxane, and adsorbents each have properties of adsorbing various volatile substances depending on its properties. In addition, each of the adsorbents has a capacity to adsorb volatile substances per volume, and the upper limit thereof is not determined for each adsorbed substance. When there are a plurality of adsorbed substances, the upper limit tends to be determined by the sum of the adsorbed substances. This brings a concern that when a large amount of substances to be adsorbed to the adsorbent, such as moisture (H₂O), is present, the upper limit of the adsorbent is exceeded in a short period of time, and the capacity of the adsorbent decreases.

In the present exemplary embodiment, siloxane remover 41 has a first stage (upstream in the gas circulation direction) where dehumidification filter 412 is disposed that is filled with a moisture absorbent for adsorbing moisture, and a second stage (downstream in the gas circulation direction) where siloxane removal filter 411 is disposed for adsorbing siloxane. With such a disposal, moisture can be sufficiently removed in dehumidification filter 412 of the first stage, so that siloxane removal filter 411 of the second stage can fully utilize the capacity of the adsorbent without being affected by moisture, and the frequency of filter replacement can be reduced.

In FIG. 8, dehumidification filter 412 and siloxane removal filter 411 are illustrated as separate members, but siloxane remover 41 may be a single component separated into an upper stage and a lower stage respectively filled with an adsorbent and a moisture absorbent.

Circulation pump 42 is a pump that circulates gas in gas circulation system 40. Circulation pump 42 circulates the gas at a flow rate set in advance.

Gas pipe 43 is a flow path of gas, and is airtightly connected to supply port 31 and exhaust port 32 of oscillator housing 30.

Humidity detector 44 detects humidity in the gas circulating through gas circulation system 40. Humidity detector 44 is used to monitor the lifetime of siloxane removal filter 411. Humidity detector 44 is, for example, a hygrometer connected to gas pipe 43. At least one humidity detector 44 needs to be disposed in the path of gas circulation system 40.

As described above, many siloxane adsorbents also adsorb moisture, and as the amount of adsorbed moisture increases, the adsorption capacity of siloxane also decreases. When not only the adsorption capacity of dehumidification filter 412 but also the adsorption capacity of siloxane removal filter 411 decreases, the humidity in the gas in gas circulation system 40 gradually increases. Therefore, monitoring the humidity of gas circulation system 40 makes it possible to predict the lifetime of siloxane removal filter 411.

It is also possible to dispose a hygrometer, as humidity detector 44, downstream of dehumidification filter 412 in the gas circulation direction, and thereby to determine which of dehumidification filter 412 and siloxane removal filter 411 is closer to the capacity limit. In addition, a plurality of hygrometers may be disposed in gas circulation system 40, and each difference may be monitored.

Note that semiconductor laser device 1 preferably includes humidity detector 44 in order to accurately detect the lifetime of siloxane removal filter 411, but does not necessarily include humidity detector 44. When a moisture absorbent having a discoloring function such as blue silica gel is applied as the moisture absorbent of dehumidification filter 412, dehumidification filter 412 can be used as humidity detector 44.

The entire gas circulation system including oscillator housing 30 and gas circulation system 40 of semiconductor laser device 1 is airtight as a system. The gas is circulated in the entire gas circulation system and contaminants such as low molecular weight siloxanes is removed by siloxane remover 41, and thereby the equilibrium siloxane concentration is controlled in the entire gas circulation system. The equilibrium siloxane concentration is a siloxane concentration when gas circulation system 40 is operated to sufficiently circulate gas throughout the system and the system reaches an equilibrium state.

Such a configuration makes it possible to prevent the end surface fouling due to the contaminants (SiOₓ) derived from siloxane and to prolong the lifetime of semiconductor laser device 1. In addition, in semiconductor laser device 1, the atmosphere of the entire gas circulation system is based on the air. This does not require a large-scale system to be used when an inert gas or the like is circulated, and makes it possible to construct the system at a relatively low cost.

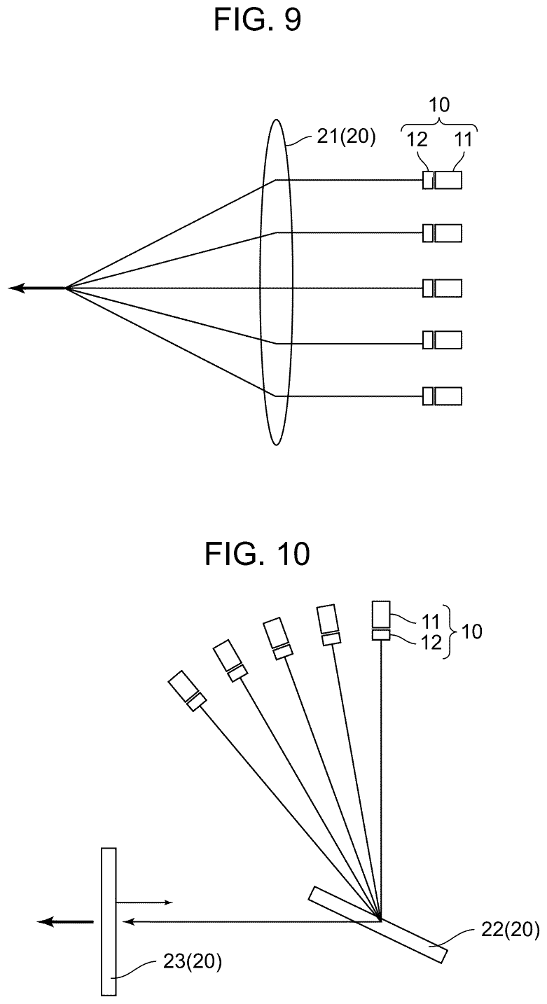

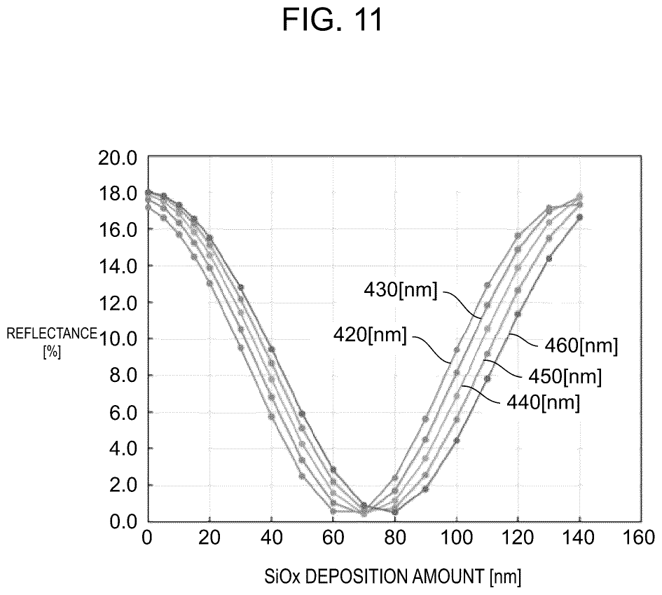

Note that in semiconductor laser device 1, a condensing method for condensing laser beams from the plurality of semiconductor laser modules 10 is not particularly limited. Examples of the condensing method of laser beams are illustrated in FIGS. 9 and 10.

FIG. 9 is a diagram schematically illustrating the principle of a light condensing method called a spatial beam combining (SBC) method.

The SBC method is a method in which the laser beams emitted from individual semiconductor laser modules 10 are condensed by condenser lens 21 (an example of optical members 20). For each semiconductor laser module 10, semiconductor laser element 11 is used that performs oscillation operation alone. A coating film (hereinafter, referred to as “STD reflection coating film”) including a dielectric multilayer film is placed on the emission end surface of semiconductor laser element 11.

The reflectance of the emission end surface is controlled to a reflectance (for example, about 5% to 20%) at which semiconductor laser element 11 operates efficiently with the STD reflection coating film. In the SBC method, since the laser beams each emitted from semiconductor laser module 10 are condensed by condenser lens 21, the condensing performance at the time of condensing is limited by the spatial positions of the semiconductor laser light sources and lens performance.

FIG. 10 is a diagram schematically illustrating the principle of a condensing method called a wavelength beam combining (WBC) method.

In the WBC method, semiconductor laser element 11 alone does not oscillate, and laser oscillation is realized by resonance with external resonant mirror 23 (an example of optical members 20) disposed in the optical system. On the emission end surface of each semiconductor laser element 11, a coating film (hereinafter, referred to as “AR coating film”) is placed that has a low reflectance so as to be as close to 0% as possible.

In the WBC method, as illustrated in FIG. 10, it is possible to combine semiconductor laser element 11 coated with AR coating, diffraction element 22 (an example of optical members 20) such as a prism or a grating, and external resonant mirror 23, thereby completely condensing laser beams having slightly different wavelengths at one point.

The WBC method can achieve higher beam quality than the SBC method. The beam quality is represented by an index representing case of condensing a beam such as BBP or M². The smaller the value of BBP or M², the higher the beam quality. When the beam quality is high, the laser beam can be condensed on a smaller spot, and the depth of focus can be taken deep. This makes it possible to take a long distance (referred to as a working distance) between the lens or the processing head front end and the workpiece, and to improve the degree of freedom of processing.

### <Required Value of Equilibrium Siloxane Concentration>

In semiconductor laser device 1, the equilibrium siloxane concentration in the entire gas circulation system is controlled to be a predetermined value or less. The required values of the equilibrium siloxane concentrations are described below.

Since the end surface deposition phenomenon due to photolysis of low molecular weight siloxanes is considered to be substantially the same as the film formation mechanism of optical chemical vapor deposition (CVD), the concentration of siloxanes that are to be the raw materials, the light intensity, the temperature, and the like are main parameters for determining the film formation rate (deposition rate).

Among these, the siloxane concentration is expected to be basically proportional to the raw material concentration except for a case in which the raw material supply is very large and the surface deposition reaction is reaction rate limiting. The light intensity and the temperature are determined from operation conditions and reliability requirements of the semiconductor laser device, and thus cannot be easily changed. Therefore, in order to reduce the deposition amount (hereinafter, referred to as “SiOₓ deposition amount”) on the emission end surface of SiOₓ, it is most important to stably control a state in which the siloxane concentration in the atmosphere is sufficiently reduced.

As a result of investigating a relationship between the deterioration of the light outputs and the SiOₓ deposition amounts (see FIG. 1 and the like) under a specific siloxane concentration, the inventors have found that: in the initial stage of deposition, the characteristics fluctuate in such a manner that the reflectance of the emission end surface is irregularly changed by the end surface deposits; and when the deposition amount increases and the irregularities shape of the surface becomes distinct, the irregularities shape of the surface, in addition to the change in reflectance, causes scattering that increases loss, and thereby deteriorates the characteristics.

FIG. 11 is a diagram illustrating changes in reflectances when SiOₓ is deposited as a flat film on a semiconductor laser element having an end surface reflectance adjusted to 18% by an end surface coating film. FIG. 11 illustrates calculation results in the case of using five laser beams each having a wavelength different from each other in 420 [nm] to 460 [nm].

In FIG. 11, the relationship between the wavelengths and the reflectances of the laser beams demonstrates that the reflectances are minimized at a thickness of about 70 nm. In other words, in the calculation assuming that the SiOₓ deposits are formed flat, the output characteristics are once decreased and then recovered again with increase in the reflectance. For reference, output fluctuations with change in the reflectance assuming that the SiOₓ deposits are a flat film are illustrated by a solid line in FIG. 1 for a laser beam with a wavelength of 440 [nm] and a laser beam with a wavelength of 450 [nm].

As illustrated in FIG. 1, the actual laser characteristics deteriorate more than calculated values. However, both the calculated values each has a turning point, and this suggests that change in the reflectance is a factor of characteristic fluctuation. It is considered that the actual decrease in the laser output is larger than the calculated value because the SiOₓ deposits are not flat but has irregularities along the light distribution, so that reflection on the end surface coating does not function normally and the loss increases.

Typically, the rated lifetime of a semiconductor laser element is often determined to be the time when the laser output drops by about 20%. In the case of the semiconductor laser element as illustrated in FIG. 1, the product lifetime is reached when 40 hours have elapsed, that is, when the SiOₓ deposits of about 70 nm have deposited in conversion into the SiOₓ deposition amount with reference to FIG. 11, and replacement of a laser light source or the like is required.

The product lifetime is very important in industrial equipment such as laser processing systems, and commonly a lifetime of at least 5,000 hours is required, with a preferred lifetime of 10,000 to 20,000 hours. In other words, as a semiconductor laser device, it is necessary to construct a siloxane concentration environment so that the SiOₓ deposition amount is 70 nm or less after an elapse of at least 5000 hours.

However, difference in the light condensing method of the semiconductor laser device may cause a more strict requirement. For example, in the case of the WBC method, the initial value of the end surface reflectance of each laser beam is small, and the reflectance increases due to deposition of SiOₓ. Increase of the reflectance generates not external resonance but normal resonance (internal resonance) in the semiconductor laser alone, and this prevents the WBC method from condensing the beams with high beam quality.

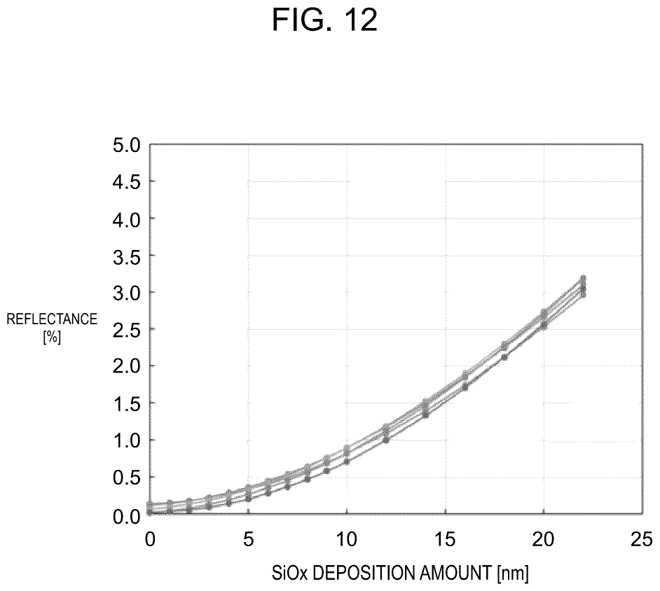

FIG. 12 is a diagram illustrating SiOₓ deposition amount dependency of reflectances in the AR coating film. FIG. 12 illustrates calculation results in the case of using five laser beams each having a wavelength between 420 [nm] to 460 [nm].

Study of the inventors have made it clear that the reflectance of the emission end surface (reflectance of the AR coating film) is preferably 1% or less in order to stably hold external resonance in the WBC method. In other words, from FIG. 12, the SiOₓ deposition amount needs to be kept to 10 nm or less.

The inventors has investigated a relationship between the SiOₓ deposition rates and the siloxane concentrations in an environment with a relatively high siloxane concentration using a single semiconductor laser element having characteristics as illustrated in FIG. 1. Since the SiOₓ deposition rate also depends on the light density and the temperature, parameters other than the siloxane concentration are matched with the use conditions in semiconductor laser device 1 as much as possible.

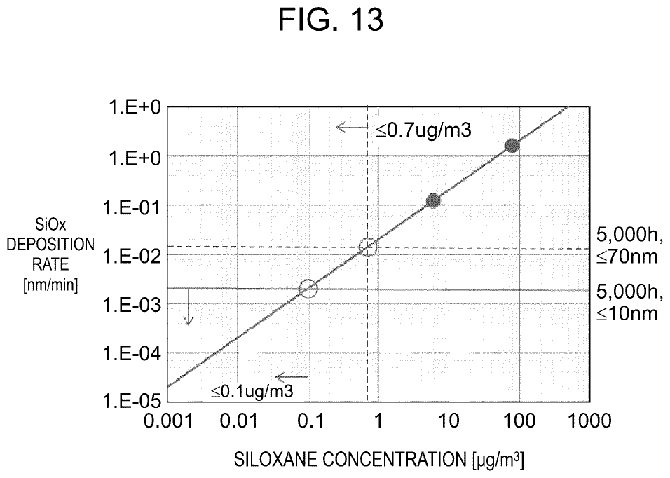

FIG. 13 is a diagram illustrating a relationship between the siloxane concentrations and the SiOₓ deposition rates.

As illustrated in FIG. 13, the SiOₓ deposition rate is proportional to the siloxane concentration. As described above, in order to guarantee the minimum 5000 hours of the product lifetime, the SiOₓ deposition amount needs to be kept to 70 nm or less at least after an elapse of 5000 hours. In the case of an external resonance laser of WBC method, the SiOₓ deposition amount needs to be kept to 10 nm or less after an elapse of 5000 hours. Therefore, from FIG. 13, the siloxane concentration required is 0.7 μg/m³ or less at least, and more preferably 0.1 μg/m³ or less. In other words, controlling the siloxane concentration to 0.7 μg/m³ or less makes it possible to keep the SiOₓ deposition amount to 70 nm or less after an elapse of 5000 hours. Furthermore, when the siloxane concentration is controlled to 0.1 μg/m³ or less, the SiOₓ deposition amount can be kept to 10 nm or less after an elapse of 5000 hours.

### <Determination of Siloxane Concentration>

The siloxane concentration in the atmosphere is generally determined by GC-MS analysis. However, semiconductor laser device 1 needs to achieve a very low siloxane concentration of 0.1 μg/m³ or less, and needs to evaluate the siloxane concentration about at or below the measurement limit of GC-MS.

The inventors have studied a method for determining a very small amount of siloxane concentration, and have developed a method for quantifying the siloxane concentration. This method is described in detail below.

The equilibrium siloxane concentration is not determined by one factor, but is considered to be affected by the circulation flow rate, the volume of the system, the siloxane inflow due to leak from the outside, the siloxane generation amount from the internal member, and the filter performance of siloxane removal filter 411. Specifically, even when the siloxane concentration in oscillator housing 30 is very low, the amount of siloxane remaining in oscillator housing 30 is relatively large when the volume of oscillator housing 30 is large. Therefore, it is considered that an SiOₓ product generated by a photochemical reaction in the vicinity of the emission end surface of the semiconductor laser element is attracted to the emission end surface (referred to as an optical tweezers effect), and the end surface contamination progresses. In addition, when the airtightness of oscillator housing 30 is low, it is considered that the siloxane concentration increases due to inflow from the outside. Furthermore, it is considered that a small amount of siloxane compounds are generated with time also from various members used in the housing.

The inventors have considered that the balance of parameters is important in order to achieve the target value of the equilibrium siloxane concentration, and have formulated the equilibrium siloxane concentration using these parameters and studied the required value for each parameter.

As a result, the equilibrium siloxane concentration has been found to be expressed by (Ca×Lg+Gs×V)/(Rs×F+Lg), where: V1 [m³] is the volume of oscillator housing 30; V2 [m³] is the volume of gas circulation system 40; V=V1+V2 [m³] is the volume of entire gas circulation system; Lg [m³/min] is the gas leak rate from the entire gas circulation system to the outside; Gs [μg/m³/min] is the siloxane generation rate inside oscillator housing 30; Ca [μg/m³] is the siloxane concentration outside oscillator housing 30; F [m³/min] is the flow rate by circulation pump 42; and Rs [%] is the siloxane removal rate of the siloxane removal filter.

Therefore, it is possible to individually control the parameters so as to satisfy the relational expression (Ca×Lg+Gs×V)/(Rs×F+Lg)≤0.7 [μg/m³], preferably (Ca×Lg+Gs×V)/(Rs×F+Lg)≤0.1 [μg/m³], thereby preventing the end surface contamination due to SiOₓ deposits.

Among these parameters, the deposition of the entire gas circulation system V [m³], the external siloxane concentration Ca [μg/m³], and the flow rate F [m³/min] can be determined relatively easily. In contrast, since the gas leak rate Lg [m³/min], the siloxane generation rate Gs [μg/m³/min], and the siloxane removal rate Rs [%] require some contrivance in the evaluation, these determination methods are to be described.

### <Determination of Gas Leak Rate Lg>

The gas leak rate Lg can be derived by measuring the oxygen concentration or the humidity. In the determination of the gas leak rate Lg, first, the entire gas circulation system is replaced with nitrogen, and a state is created in which the residual oxygen concentration is lowered to about 100 ppm or less. Thereafter, while the system is closed, an oxygen concentration meter is connected to measure a time change in the internal oxygen concentration. Change in oxygen concentration is measured over a period ranging from a few hours to 100 hours, and thereby the gas leak rate Lg of the system can be calculated from the external oxygen concentration (about 20%) and the change rate of the oxygen concentration.

The gas leak rate Lg can also be derived by measuring the internal humidity by the same method. However, in the case of humidity measurement, since the measurement accuracy is on the order of %, the measurement accuracy is considered to be slightly inferior to the oxygen concentration measurement. It is also possible to derive the gas leak rate Lg using a helium leak detector. However, although the helium leak detector is excellent in determining a local leak spot, it is not good at measuring the leak amount of the entire system. For this reason, it is most convenient and suitable to use the measurement of the oxygen concentration for the determination of the gas leak rate Lg from the entire gas circulation system to the outside.

Note that the determination of the gas leak rate Lg is preferably performed in the entire gas circulation system including oscillator housing 30 and gas circulation system 40. However, when the gas leak rate in gas circulation system 40 is sufficiently smaller than the gas leak rate of oscillator housing 30, leak rate measurement of only oscillator housing 30 may be used as an alternative.

### <Determination of Siloxane Generation Rate Gs>

A small amount of siloxane may be generated from various components in oscillator housing 30, and it is necessary to select a material for each component to be used, study a cleaning method, and the like. In other words, if components are used that prevent generation of siloxane to some extent, it is difficult to completely eliminate generation of siloxane, and the absolute amount of generation of siloxane increases as the entire system is larger.

In the determination of the siloxane generation rate Gs, first, gas circulation system 40 is operated to sufficiently circulate gas throughout the system, and the siloxane concentration inside is reduced to an equilibrium state. Thereafter, the circulation of the gas is stopped, and the system is left to stand in a closed state for about 100 hours. After being left to stand for a certain period of time, the gas inside oscillator housing 30 is collected without passing through siloxane removal filter 411, and the siloxane concentration is measured. Comparing the siloxane concentrations before and after standing makes it possible to calculate the siloxane generation rate Gs. The standing time may be adjusted depending on the siloxane generation amount per unit time, and standing for a long period of time makes it possible to measure a smaller amount of siloxane generation rate Gs.

The siloxane generation rate Gs is slightly affected by the gas leak rate Lg and the external siloxane concentration Ca. Usually, in oscillator housing 30 and gas circulation system 40 in which airtightness measures have been sufficiently taken, the influence of the gas leak rate Lg and the external siloxane concentration Ca is slight, and it can be often determined that the detected siloxane is siloxane generated inside oscillator housing 30. However, the measured value of the siloxane concentration may be compared to the increase amount in the siloxane concentration assumed from the gas leak rate Lg, and if necessary, a correction may be added to the siloxane generation rate Gs based on the gas leak rate Lg and the external siloxane concentration Ca.

### <Determination of Siloxane Removal Rate Rs>

The siloxane removal rate Rs is a ratio of the amount of siloxane removed when the gas containing siloxane passes through siloxane removal filter 411 once. In the determination of the siloxane removal rate Rs, first, a gas containing siloxane to some extent (for example, about 10 μg/m³) is prepared as a gas to be input to siloxane removal filter 411. Then, the siloxane concentration when the siloxane does not pass through siloxane removal filter 411 and the siloxane concentration when the siloxane passes through siloxane removal filter 411 are measured by GS/MS. From the ratio of these, the siloxane removal rate Rs can be calculated.

### <Required Value for Flow Rate F (Replacement Efficiency F/V)>

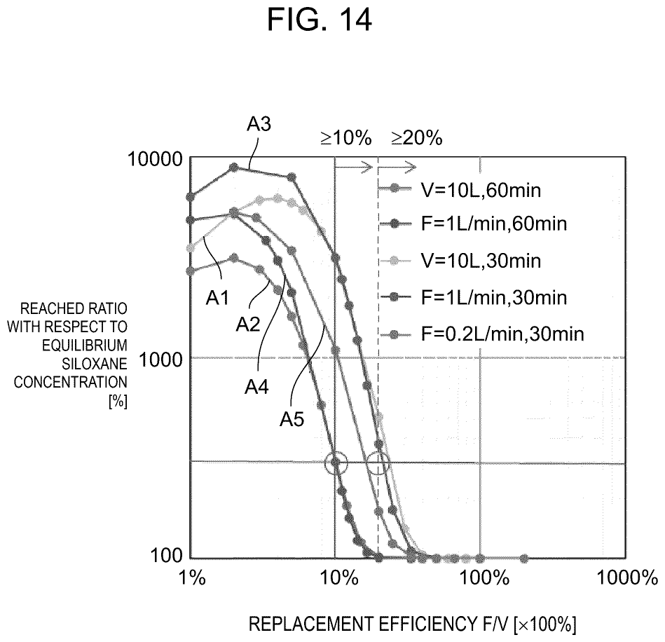

FIG. 14 is a diagram illustrating a relationship between the replacement efficiency F/V [%] per minute by circulation pump 42 and the reached siloxane concentration. The reached siloxane concentration is a siloxane concentration after an elapse of a predetermined time from the start of circulation.

FIG. 14 illustrates the results of calculating the internal siloxane concentrations (reached siloxane concentrations) at 30 minutes and 60 minutes after the start of circulation in several patterns. Specifically, the reached siloxane concentrations after 30 minutes and 60 minutes in the case of V=10 L (constant) are respectively represented by A1, A2, the reached siloxane concentrations after 30 minutes and 60 minutes in the case of F=1 L/min (constant) are respectively represented by A3, A4, and the reached siloxane concentration after 30 minutes in the case of F=0.2 L/min (constant) is represented by A5. The replacement efficiency F/V [%] is a ratio between the circulation flow rate F [m³/min] by circulation pump 42 and the volume V=V1+V2 [m³] of the entire system. The reached siloxane concentration is expressed as a ratio to the equilibrium siloxane concentration with the equilibrium siloxane concentration as 100%.

The replacement efficiency F/V represents the ratio of gas passing through siloxane removal filter 411 per unit time by circulation to the gas in the entire system. Therefore, as the value is larger, the equilibrium siloxane concentration is reached faster.

As semiconductor laser device 1 is assumed to start laser emission after sufficient circulation is performed, but in device start-up, there is a waiting time until the siloxane concentration reaches a neighborhood of the equilibrium siloxane concentration. Normally, the device start-up time is allowed to be about 30 minutes to 60 minutes at the longest. Therefore, considering that the concentration can be reduced to about 3 times the equilibrium siloxane concentration within this time, from FIG. 14, the replacement efficiency F/V needs to be 10% or more, more preferably 20% or more.

### <Required Value for Siloxane Removal Rate Rs>

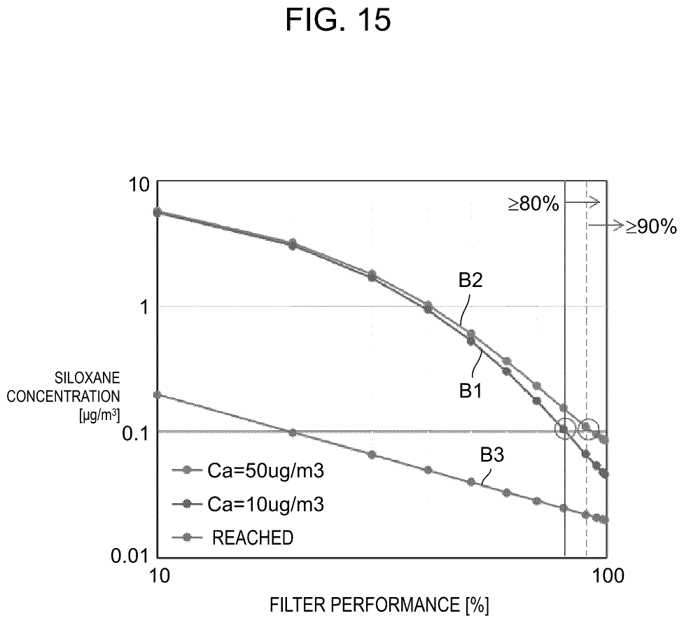

FIG. 15 is a diagram illustrating a relationship between the filter performance (siloxane removal rates Rs) of siloxane removal filter 411 and the internal siloxane concentrations of oscillator housing 30. In FIGS. 15, B1 and B2 represent the internal siloxane concentrations 60 minutes after the start of circulation in the case of the external siloxane concentrations Ca=10 μg/m³ and 50 μg/m³, respectively, and B3 represents the equilibrium siloxane concentration reached when Ca=10 μg/m³.

From FIG. 15, although depending on the external siloxane concentration Ca and other parameters, the siloxane removal rate Rs [%] of siloxane removal filter 411 needs to be at least 80% or more, more preferably 90% or more, in order to achieve a siloxane concentration of 0.1 μg/m³ or less.

### <Required Value for Gas Leak Rate Lg>

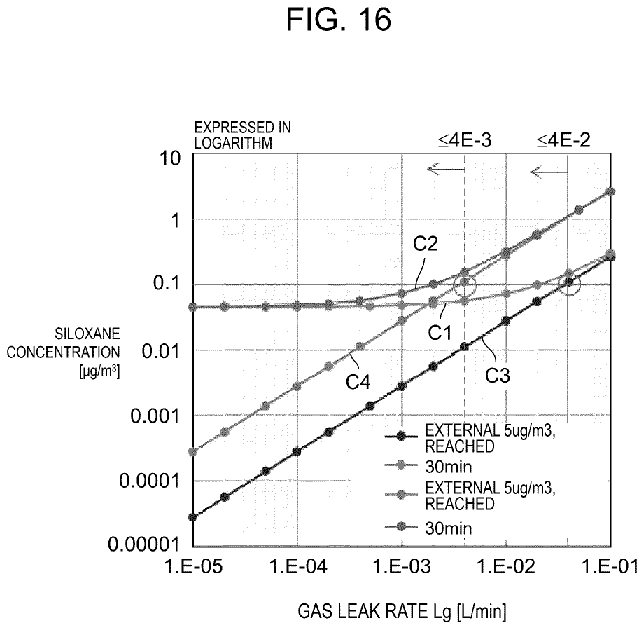

FIG. 16 is a diagram illustrating the leak rate dependency of the siloxane concentration when the external siloxane concentration Ca is 5 μg/m³ and when the external siloxane concentration Ca is 50 μg/m³. In FIG. 16, C1 and C2 represent the internal siloxane concentrations 30 minutes after the start of circulation in the cases of the external siloxane concentrations Ca=5 g/m³ and 50 μg/m³, respectively, and C3 and C4 represent the equilibrium siloxane concentrations reached after an elapse of sufficient time from the start of circulation in the case of the external siloxane concentrations Ca=5 μg/m³ and 50 μg/m³, respectively.

As for the siloxane concentration, a siloxane concentration of 5 g/m³ or less can be realized in an environment in which the siloxane concentration is controlled to some extent, but in an environment in which no special control is performed, operation may be required in an environment with a high siloxane concentration of about 50 μg/m³. In such an external environment, in order to set the siloxane concentration inside oscillator housing 30 to 0.1 μg/m³ or less, the gas leak rate Lg is preferably 4×10⁻² L/min or less, and more preferably 4×10⁻³ L/min or less, from FIG. 16.

<Realization of Airtight Housing with Low Leak Rate>

In order to enhance airtightness of oscillator housing 30 and airtightness of gas circulation system 40, it is important to take an airtightness measure for the seal of each connection part. By basically using an O-ring for the seal, a certain degree of airtightness can be expected.

However, since the O-ring is known to be a siloxane generation source, it is desirable to select a fluorine-rubber-based O-ring, and to use an O-ring having residual siloxane components that have been sufficiently reduced by performing appropriate cleaning, baking, or the like. For the seal in the circulation system, a simple one-touch connector or the like is not so preferable, and a connection method using a metal pipe or a metal connection part is more preferable.

### <Required Value for Siloxane Generation Rate Gs>

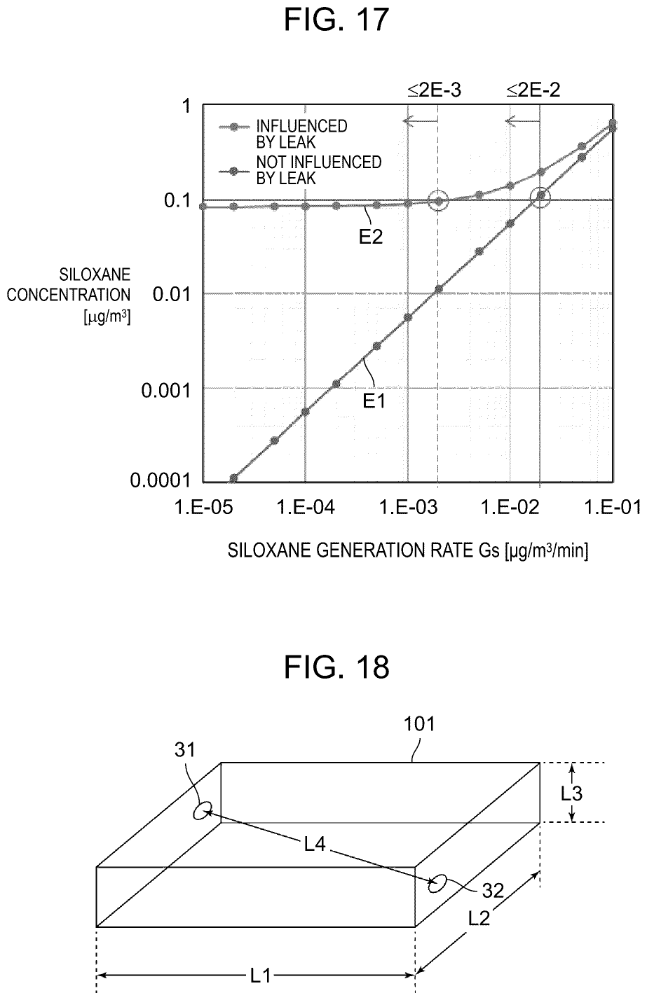

FIG. 17 is a diagram illustrating a relationship between the siloxane generation rates Gs and the siloxane concentrations inside oscillator housing 30. In FIG. 17, E1 represents the siloxane concentration when there is no influence of leak from the outside, and E2 represents the siloxane concentration when there is an influence of leak from the outside.

As can be seen from FIG. 17, when there is no influence of leak from the outside, the equilibrium siloxane concentration can be 0.1 μg/m³ or less if the siloxane generation rate is 2×10⁻² μg/m³/min or less. In contrast, it is found that when the influence of leak from the outside is large, the siloxane generation rate Gs needs to be 2×10⁻³ μg/m³/min or less.

### <Selection and Cleaning of Members>

The generation of siloxane inside oscillator housing 30 is naturally caused by generation of siloxane over time from members inside the housing. The cause of generation of siloxane is roughly divided into two patterns.

The first pattern is a pattern in which siloxane or the like floating in the air is deposited on the member surface and becomes a generation source. In this case, since siloxanes or siloxane-like molecules are not present in the principal component of the member, it can be said that siloxane is not generated if the member is used after surface contamination is removed. For removing the siloxane deposited on the surface of such a member, cleaning with an organic solvent or baking with an oven is effective. Since low molecular weight siloxanes have a high vapor pressure, a considerable part of siloxanes can be removed by performing baking at a high temperature of 100° C. or more for a certain period of time or more.

The second pattern is a pattern in which siloxane is contained inside the member, that is, a pattern in which siloxanes and molecules having a Si—O-skeleton similar to siloxane are contained in the principal component or the accessory component of the member. O-rings and the like including a silicone rubber have a principal component itself of silicone that may decompose with time degradation and release a low molecular weight siloxane. For this reason, use of the O-rings including a silicone rubber and the like should be avoided. In the case of fluorine-rubber-based O-rings, silicone is not contained as a principal component. However, it has been found that: siloxane is often contained in a release agent at the time of molding; and residual components of the release agent remaining in micropores of the fluorine-rubber causes siloxane generation. These residual components can also be removed by sufficient cleaning and baking.

It is necessary to check whether other resins are also made of siloxane-free material, and to consider the use or non-use of the member and a method of pretreatment. Also in gas circulation system 40, attention needs to be paid because a siloxane component may remain in an internal flow path such as a flow rate adjustment valve or a flow rate meter. It is preferable that an oil-free circulation pump be selected for circulation pump 42, and the gas contact portion be siloxane-free.

### <Positional Relationship Between Supply Port and Exhaust Port>

FIG. 18 is a diagram for describing a positional relationship between supply port 31 and exhaust port 32 in oscillator housing 30.

As illustrated in FIG. 18, when three sides of the smallest cuboid 101 enclosing oscillator housing 30 are L1, L2, and L3, and the magnitude relationship among the sides is L1≥L2>L3, supply port 31 and exhaust port 32 are disposed such that shortest distance L4 of the gas flow path from supply port 31 to exhaust port 32 satisfies L4≥L2.

In oscillator housing 30, the gas flowing in from supply port 31 spreads into the housing and flows out from exhaust port 32. As a result, siloxane generated inside oscillator housing 30 and siloxane flowing in from the outside are circulated to be removed. Therefore, it is important to replace the internal gas as uniformly as possible.

Although the internal gas flow path can be controlled by various methods, satisfying the above relationship as a basic disposal makes it possible to minimize the internal flow rectification member and the like to efficiently replace the gas in the housing.

The above describes to what extent the equilibrium siloxane concentration in oscillator housing 30 needs to be reduced in order to guarantee the lifetime of semiconductor laser device 1. The above also describes the required values of the parameters required to reduce the equilibrium siloxane concentration to the required levels. It is the internal equilibrium siloxane concentration that ultimately determines the lifetime, and all measures can be taken to achieve the required equilibrium siloxane concentration and individual parameters, not just those described in the present disclosure.

### Second Exemplary Embodiment

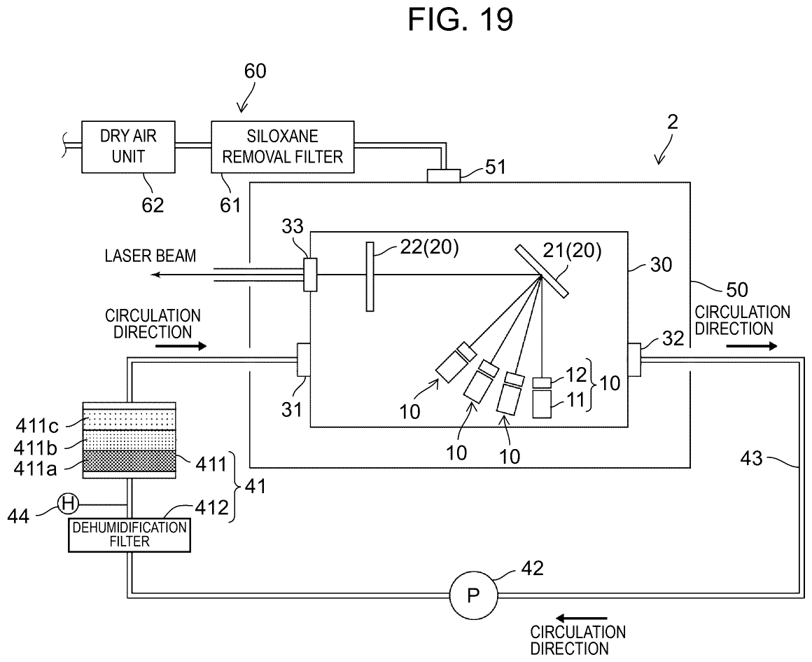

FIG. 19 is a diagram illustrating a configuration of semiconductor laser device 2 according to a second exemplary embodiment. Components that are the same as or correspond to those in the first exemplary embodiment are denoted by the same reference marks.

Semiconductor laser device 2 includes external housing 50 outside oscillator housing 30. Gas supply line 60 is connected to external housing 50. Since components other than the components related to external housing 50 and gas supply line 60 are similar to those in the first exemplary embodiment, description thereof is omitted.

As described in the first exemplary embodiment, the siloxane concentration inside oscillator housing 30 can be reduced by reducing the gas leak rate Lg of oscillator housing 30. However, even if the gas leak rate Lg is low, the influence on the equilibrium siloxane concentration inside oscillator housing 30 increases when the external siloxane concentration Ca is high. Therefore, also the external siloxane concentration Ca is preferably low.

However, in a factory or the like, it is difficult to constantly keep the siloxane concentration low for each use environment. Semiconductor laser device 2 includes external housing 50, and gas having a relatively low siloxane concentration is constantly supplied from gas supply line 60 via supply port 51 of external housing 50. The siloxane concentration of the gas supplied from gas supply line 60 is preferably 10 μg/m³ or less. As a result, the external siloxane concentration Ca viewed from oscillator housing 30 can be reduced, specifically, to 10 μg/m³ or less.

It is sufficient that a siloxane concentration of, for example, about 1 to 10 μg/m³ can be achieved inside external housing 50, so that airtightness of external housing 50 itself is not necessary. For example, it is sufficient to cause dry air generated by dry air unit 62 or gas that has passed through siloxane removal filter 61 to flow into external housing 50 from supply port 51 of external housing 50. Note that in gas supply line 60 of FIG. 19, dry air unit 62 and siloxane removal filter 61 are used in combination, but it is acceptable to use only one of them.

As described above, semiconductor laser devices 1 and 2 according to the exemplary embodiments include the following features singly or in an appropriate combination.

In other words, semiconductor laser devices 1 and 2 each include semiconductor laser element 11 having an emission end surface of laser light, oscillator housing 30 having airtightness, and gas circulation system 40 that has circulation pump 42 and siloxane remover 41 and is connected to supply port 31 and exhaust port 32 of oscillator housing 30. In oscillator housing 30, semiconductor laser elements 11 are each disposed in a state in which the emission end surface of the laser light is exposed, and optical members 20 and an electric wiring member (not illustrated) are also disposed. When gas circulation system 40 is operated, the equilibrium siloxane concentration in oscillator housing 30 is 0.1 μg/m³ or less.

According to semiconductor laser devices 1 and 2, it is possible to prevent the end surface fouling due to the fouling substances derived from siloxane in semiconductor laser element 11 and to improve the reliability of semiconductor laser devices 1 and 2. In addition, it is possible to prolong the lifetimes of semiconductor laser devices 1 and 2.

Furthermore, semiconductor laser devices 1 and 2 satisfies the relational expression (Ca×Lg+Gs×V)/(Rs×F+Lg)≤0.1 [μg/m³], where: V1 [m³] is the volume of oscillator housing 30; V2 [m³] is the volume of gas circulation system 40; V=V1+V2 [m³] is the volume of the entire gas circulation system including oscillator housing 30 and gas circulation system 40; Lg [m³/min] is the gas leak rate from the entire gas circulation system to the outside; Gs [μg/m³/min] is the siloxane generation rate inside the entire gas circulation system; Ca [μg/m³] is the siloxane concentration outside oscillator housing 30; F [m³/min] is the flow rate by circulation pump 42; and Rs [%] is the siloxane removal rate of siloxane remover 41. That is, the equilibrium siloxane concentration is expressed by (Ca×Lg+Gs×V)/(Rs×F+Lg)≤0.1 [μg/m³]. As a result, the plurality of parameters can be appropriately controlled so that the equilibrium siloxane concentration satisfies the required value.

In semiconductor laser devices 1 and 2, the gas leak rate Lg is 4×10⁻³ L/min or less. Therefore, if semiconductor laser devices 1 and 2 are used in an environment with a high external siloxane concentration (for example, about 50 μg/m³), the equilibrium siloxane concentration can be set to 0.1 μg/m³ or less.

In semiconductor laser devices 1 and 2, the siloxane generation rate Gs is 2×10⁻³ μg/m³/min or less. As a result, even if the influence of leak from the outside is large, the equilibrium siloxane concentration can be set to 0.1 μg/m³ or less.

In semiconductor laser devices 1 and 2, the replacement efficiency F/V represented by the ratio of the flow rate F to the volume V of the entire gas circulation system is 20% or more. As a result, the equilibrium siloxane concentration inside oscillator housing 30 of each of semiconductor laser devices 1 and 2 can be set to 0.1 μg/m³ or less in a relatively short time.

In semiconductor laser devices 1 and 2, the siloxane removal rate Rs is 80% or more. As a result, if the external siloxane concentration Ca is high or the siloxane generation rate Gs is high, the equilibrium siloxane concentration inside oscillator housing 30 can be set to 0.1 μg/m³ or less.

In semiconductor laser devices 1 and 2, the siloxane concentration Ca outside the entire gas circulation system is 50 μg/m³ or less. As a result, the required value of the gas leak rate Lg can be reduced, and the equilibrium siloxane concentration can be easily set to 0.1 μg/m³ or less.

In semiconductor laser devices 1 and 2, siloxane remover 41 is connected between supply port 31 of oscillator housing 30 and the exhaust port of circulation pump 42. As a result, circulating the gas makes it possible to send the gas with a minimized siloxane concentration to oscillator housing 30, and to optimize the siloxane concentration distribution inside the gas circulation system.

In semiconductor laser devices 1 and 2, siloxane remover 41 includes dehumidification filter 412 that adsorbs moisture of the circulating gas to perform dehumidification and siloxane removal filter 411 that mainly removes siloxane. Siloxane removal filter 411 is disposed downstream of dehumidification filter 412 in the gas circulation direction. Since moisture can be sufficiently removed in the upstream dehumidification filter 412, the downstream siloxane removal filter 411 can fully utilize the capacity of the adsorbent without being affected by moisture.

In semiconductor laser devices 1 and 2, length L4 of the shortest path through which the gas flows from supply port 31 to exhaust port 32 in oscillator housing 30 is longer than length L2 of the second longest side among the three sides of the smallest cuboid 101 enclosing oscillator housing 30. As a result, it is possible to minimize the flow rectification member and the like disposed inside oscillator housing 30 and to efficiently replace the gas in the housing.

In semiconductor laser devices 1 and 2, oscillator housing 30 has optical window 33 for emitting a laser light, and the wavelength of the laser light emitted from optical window 33 is 550 nm or less. This makes it possible to prevent end surface fouling derived from siloxane in a GaN-based semiconductor laser element that emits blue laser light.

Semiconductor laser device 2 includes external housing 50 that houses oscillator housing 30, and the siloxane concentration inside external housing 50 is 10 μg/m³ or less. As a result, since the external siloxane concentration Ca decreases, the equilibrium siloxane concentration inside oscillator housing 30 can be easily set to 0.1 μg/m³ or less.

Semiconductor laser device 2 includes gas supply line 60 connected to supply port 51 of external housing 50, and the siloxane concentration of the gas supplied from gas supply line 60 to external housing 50 is 10 μg/m³ or less. This allows the inside of external housing 50 to be kept at 10 μg/m³ or less.

In semiconductor laser device 2, gas supply line 60 includes at least one of siloxane removal filter 61 (filter for removing siloxane) and dry air unit 62. This makes it possible to easily set the siloxane concentration of the gas supplied from gas supply line 60 to external housing 50 to 10 μg/m³ or less.

Although the invention made by the inventor of the present invention has been specifically described above based on the exemplary embodiments, the present invention is not limited to the above exemplary embodiments, and can be modified without departing from the spirit of the present invention.

It should be construed that the exemplary embodiments disclosed herein is illustrative in all aspects, and is not restrictive. The scope of the present disclosure is represented by the scope of the claims and not by the above description, and it is intended that all modifications within the sense and scope equivalent to the claims are involved in the scope of the present disclosure.

According to the present disclosure, it is possible to prevent end surface fouling due to a fouling substances derived from siloxane in a semiconductor laser element and to improve reliability of the semiconductor laser device.

### INDUSTRIAL APPLICABILITY

The semiconductor laser device of the present disclosure is useful for applications such as welding, cutting, drilling, and material processing as a laser processing system.

### REFERENCE MARKS IN THE DRAWINGS

1, 2 semiconductor laser device
10 semiconductor laser module
11 semiconductor laser element
12 intra-module optical component
20 optical member
30 oscillator housing
31 supply port
32 exhaust port
33 optical window
40 gas circulation system
41 siloxane remover
411 siloxane removal filter
412 dehumidification filter
43 gas pipe
44 humidity detector
50 external housing
60 gas supply line
61 siloxane removal filter
62 dry air unit

1. A semiconductor laser device, comprising:
a semiconductor laser element having an emission end surface of laser light;
an oscillator housing having airtightness; and
a gas circulation system including a circulation pump and a siloxane remover and connected to a supply port and an exhaust port of the oscillator housing,
wherein in the oscillator housing, the semiconductor laser element is disposed with the emission end surface of the laser light being exposed from the oscillator housing, and an optical member and an electric wiring member are also disposed, and
when the gas circulation system is operated, the oscillator housing has an inside having an equilibrium siloxane concentration of 0.1 μg/m³ or less.

2. The semiconductor laser device according to claim 1, wherein a relational expression:
$$( Ca \times Lg + Gs \times V ) / ( Rs \times F + Lg ) \leq 0.1 [ μg / {m}^{3} ]$$
is satisfied, where:
V1 [m³] is a volume of the oscillator housing;
V2 [m³] is a volume of the gas circulation system;
V=V1+V2 [m³] is a volume of an entire gas circulation system including the oscillator housing and the gas circulation system;
Lg [m³/min] is a gas leak rate from the entire gas circulation system to an outside;
Gs [μg/m³/min] is a siloxane generation rate inside the entire gas circulation system;
Ca [μg/m³] is a siloxane concentration outside the oscillator housing;
F [m³/min] is a flow rate by the circulation pump; and
Rs [%] is a siloxane removal rate of the siloxane remover.

3. The semiconductor laser device according to claim 2, wherein
the gas leak rate Lg is 4×10⁻³ L/min or less.

4. The semiconductor laser device according to claim 2, wherein
the siloxane generation rate Gs is 2×10⁻³ μg/m³/min or less.

5. The semiconductor laser device according to claim 2, wherein
a ratio of the flow rate F to the volume V of the entire gas circulation system represents a replacement efficiency F/V, the replacement efficiency F/V being 20% or more.

6. The semiconductor laser device according to claim 2, wherein
the siloxane removal rate Rs is 80% or more.

7. The semiconductor laser device according to claim 2, wherein
the siloxane concentration outside the oscillator housing is 50 μg/m³ or less.

8. The semiconductor laser device according to claim 1, wherein
the siloxane remover is connected between the supply port of the oscillator housing and an exhaust port of the circulation pump.

9. The semiconductor laser device according to claim 1, wherein
the siloxane remover includes a dehumidification filter that adsorbs moisture of a circulating gas and performs dehumidification, and a siloxane removal filter that mainly removes siloxane, and
the siloxane removal filter is disposed downstream of the dehumidification filter in a gas circulation direction.

10. The semiconductor laser device according to claim 1, wherein
the oscillator housing has a shortest path through which gas flows from the supply port to the exhaust port, the oscillator housing has a smallest cuboid among cuboids that enclose the oscillator housing, the smallest cuboid has three sides, and the shortest path has a length longer than a second longest side among the three sides.

11. The semiconductor laser device according to claim 1, wherein
the oscillator housing has an optical window that emits laser light, and
the laser light emitted from the optical window has a wavelength of 550 nm or less.

12. The semiconductor laser device according to claim 7, further comprising an external housing that houses the oscillator housing, wherein
the external housing has an inside having a siloxane concentration of 10 μg/m³ or less.

13. The semiconductor laser device according to claim 12, further comprising a gas supply line connected to a supply port of the external housing, wherein
the gas supply line supplies a gas to the external housing, the gas having a siloxane concentration of 10 μg/m³ or less.

14. The semiconductor laser device according to claim 13, wherein
the gas supply line includes at least one of a filter for removing siloxane and a dry air unit.
